(19) United States
(12) Patent Application Publication
(10) Pub. No.: US 2005/0173723 A1
(43) Pub. Date: Aug. 11, 2005

(54) Light-emitting diode structure and a method for manufacturing the light-emitting diode

(76) Inventors: Shih-Chien Weng, Danshuei Township (TW); Kai-Jen Yu, Shulin City (TW)

Correspondence Address: BRUCE H. TROXELL;SUITE 1404, 5205 LEESBURG PIKE, FALLS CHURCH, VA, 22041, US

(21) Appl. No.: 11/044,075

(22) Filed: Jan. 28, 2005

(30) Foreign Application Priority Data
Feb. 10, 2004 (CN) 200410022883.2

(51) Int. Cl. H01L 29/24

(52) U.S. Cl. 257/100

(57) ABSTRACT

A light-emitting diode structure and a method for manufacturing the light-emitting diode structure. The method includes steps of: preparing a metal plane blank in a production line and punching the blank with an upper mold section to form a concave central section protruding from the blank; punching the concave central section with a lower mold section in a reverse direction, whereby a bottom of the central section is formed with at least one rigid wall defining a cavity; pressing a predetermined position of the central section with another upper mold section in a direction the same as the moving direction of the upper mold section to form a bowl seat on the central section for fixing a chip in the bowl seat; and forming a grid structure on a periphery of the central section so as to complete a model body. The model body has a central section and a connecting section. The central section has a bowl seat for fixing therein a chip. The central section is defined as a cathode end. The connecting section has at least two contact pins as anode ends.

### BACKGROUND OF THE INVENTION

The present invention is related to a light-emitting diode structure and a method for manufacturing the light-emitting diode, and more particularly to a light-emitting diode with greatly enhanced heat-radiating effect.

The conventional light-emitting diodes (LED) have been widely applied to various electronic products. The LED can be used as an indicator lamp with weaker light-emitting efficiency or used in those illuminators with high intensity, such as outdoor panels and traffic signs. Basically, the LED utilizes a PN interface working under forward bias. Under forward bias, a great amount of electronic holes are filled into P-type zone, while a great amount of electrons are filled into N-type zone. In the vacant zone, a few carriers of the electronic holes and the electrons will respectively fill into the other zone. In the instant of combination of the carriers, photons equal to the energy gap are radiated to achieve light-emitting effect. The conventional LED are made by punching multiple conductive metal brackets connected with each other and arranged at equal intervals. The bracket is electroplated with a silver coating. A semiconductor chip is fixed on the bracket to serve as the light source of the LED. Two ends of the lead are respectively connected to the bracket and the chip to form a cathode contact pin and an anode contact pin. An epoxy resin is poured onto upper side of the bracket as a transparent body for sealing the chip and the lead.

It is well known by those skilled in this field that most of the energy of the LED is transformed into heat. In the case that the heat is not dissipated, the chip will overheat and damage. A part of the heat accumulates in the transparent body, while another part of the heat is dissipated through the first and second contact pins of the bracket. The transparent body is made of epoxy resin which has poor heat conductivity. Therefore, most of the heat generated by the chip accumulates in the transparent body without effectively dissipating. Only the bracket serves to conduct and radiate the heat so that the heat-radiating efficiency is lower.

Taiwanese Utility Model Patent Application No. 90201309 entitled “light-emitting diode bracket” discloses a bracket having a pair of contact pins in addition to the original first and second contact pins. The heat generated by the chip can be dissipated through the four contact pins so as to improve the above problem. However, practically, the heat-radiating efficiency of such light-emitting diode bracket is still limited.

In all the conventional LED lamps, the upper end of the bracket is packaged with a transparent body. In addition, the bottom area of the cathode bowl is entirely covered by an adhesive glue with a thickness of about 20 μm˜100 μm for adhering the LED chip. The glue can be silver glue, white glue and insulating glue. The transparent body and the adhesive glue hinder the generated heat from being conducted and dissipated. When turned on, different LED chips with different powers will proportionally generate different amounts of heat. It is critical to the lighting effect of the light-emitting diode whether the heat can be quickly conducted and dissipated.

Taiwanese Patent Application No. 88218394 entitled “light-emitting diode bracket” and Taiwanese Patent Application No. 90201308 entitled “light-emitting diode bracket” disclose bracket structure having additional contact pins for enhancing the heat-dissipating effect. However, these Patents fail to teach special improvement of the structure of the LED. In fact, by means of changing the structure of the LED, the heat-radiating efficiency can be apparently enhanced. For example, without increasing the packaging area of the bracket, the bracket can be designed with a specific space pattern having larger heat-radiating area.

### SUMMARY OF THE INVENTION

It is therefore a primary object of the present invention to provide an improved light-emitting diode structure and a method for manufacturing the light-emitting diode structure. The heat-radiating area of the light-emitting diode is greatly increased for achieving better heat-radiating efficiency.

According to the above object, the method manufacturing the light-emitting diode structure includes steps of: preparing a metal plane blank in a production line and punching the blank with an upper mold section to form a concave central section protruding from the blank; punching the concave central section with a lower mold section in a reverse direction, whereby a bottom of the central section is formed with at least one rigid wall defining a cavity; pressing a predetermined position of the central section with another upper mold section in a direction the same as the moving direction of the upper mold section to form a bowl seat on the central section for fixing a chip in the bowl seat; and forming a grid structure on a periphery of the central section so as to complete a model body. The model body has a central section and a connecting section. The central section has a bowl seat for fixing therein a chip. The central section is defined as a cathode end. The connecting section has at least two contact pins as anode ends.

The present invention can be best understood through the following description and accompanying drawings wherein:

### BRIEF DESCRIPTION OF THE DRAWINGS

FIG. 1 is a perspective view of the light-emitting diode of the present invention, in which the phantom line shows the arrangement of the chip and the package of the transparent body;

FIG. 2 is a sectional view according to FIG. 1;

FIG. 3 is a flow chart of the method of the present invention, showing that a metal plane blank is punched to form the model body;

FIG. 4 is a perspective sectional view according to step a of FIG. 3;

FIG. 5 is a perspective sectional view according to step b of FIG. 3, showing that after punched, the model body is formed with continuously arranged rigid walls defining a cavity;

FIG. 6 is a perspective sectional view according to step c of FIG. 3;

FIG. 7 is a plane view according to step d of FIG. 3; and

FIG. 8 is a perspective sectional view according to step d of FIG. 3.

### DETAILED DESCRIPTION OF THE PREFERRED EMBODIMENTS

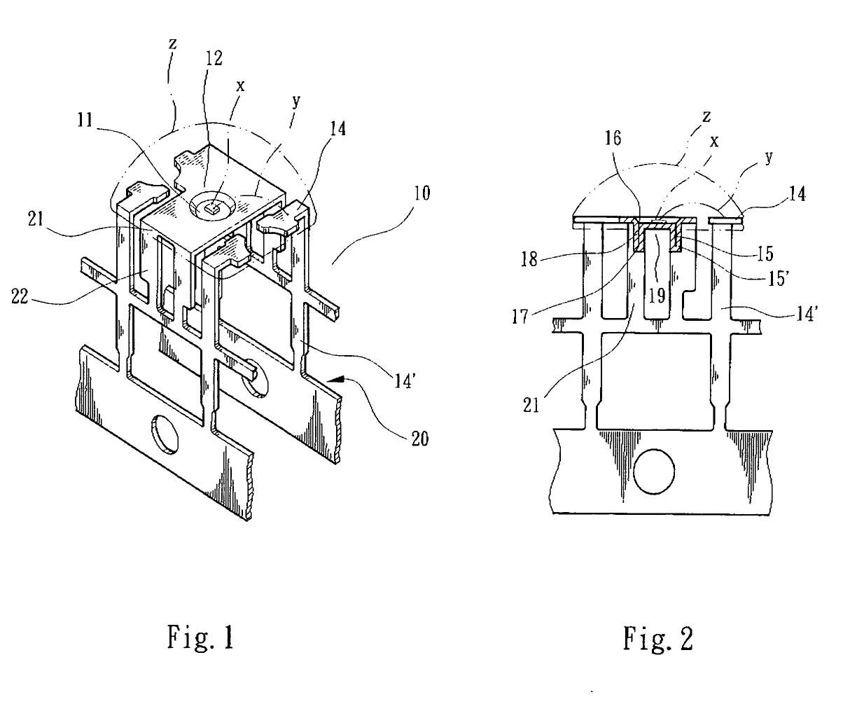

Please refer to FIGS. 1 and 2. The light-emitting diode structure of the present invention includes a model body 10 having a central section 12 and a connecting section 14. The central section 12 has a bowl seat 11 in which a chip x is fixed. The central section 12 is defined as a cathode end. The connecting section 14 has contact pins 14′ as anode ends. The contact pins 14′ are electrically connected with a circuit board. The section enclosed by the phantom line of FIG. 1 is a light-emitting diode product of the present invention. The chip x is fixed in the bowl seat 11 of the central section 12 and two ends of a lead y are respectively connected with the chip x and the connecting section 14. A transparent body z made of epoxy resin is disposed on upper side of the model body 10 to seal the chip x, lead y and the top end sections of the central section 12 and the connecting section 14.

In a preferred embodiment, the model body 10 has multiple layers of rigid walls 15, 15′ arranged from the central section 12 to outer side. The rigid walls 15 define a cavity 19. Each rigid wall 15, 15′ has a ridge section 16 and a hollow section 17 adjoining two adjacent rigid walls 15, 15′. Two adjacent rigid walls 15, 15′ define therebetween a gap 18 as a heat-radiating groove.

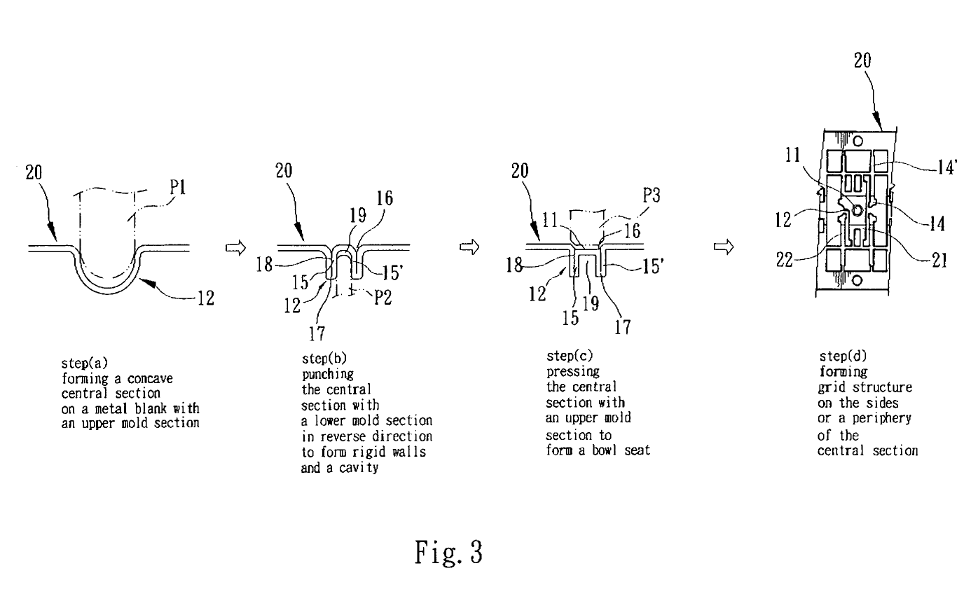

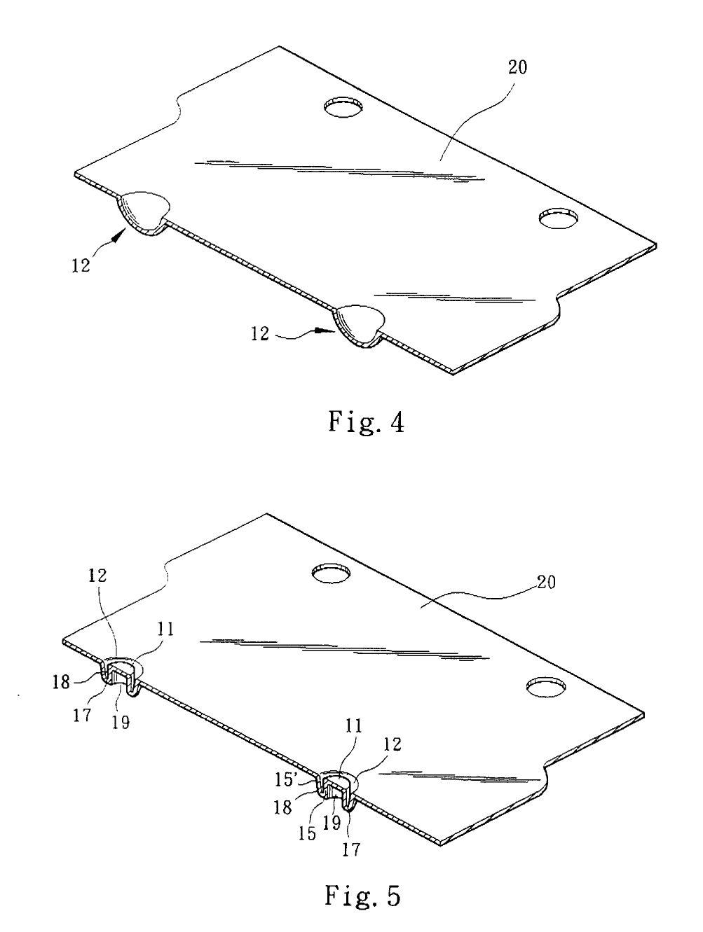

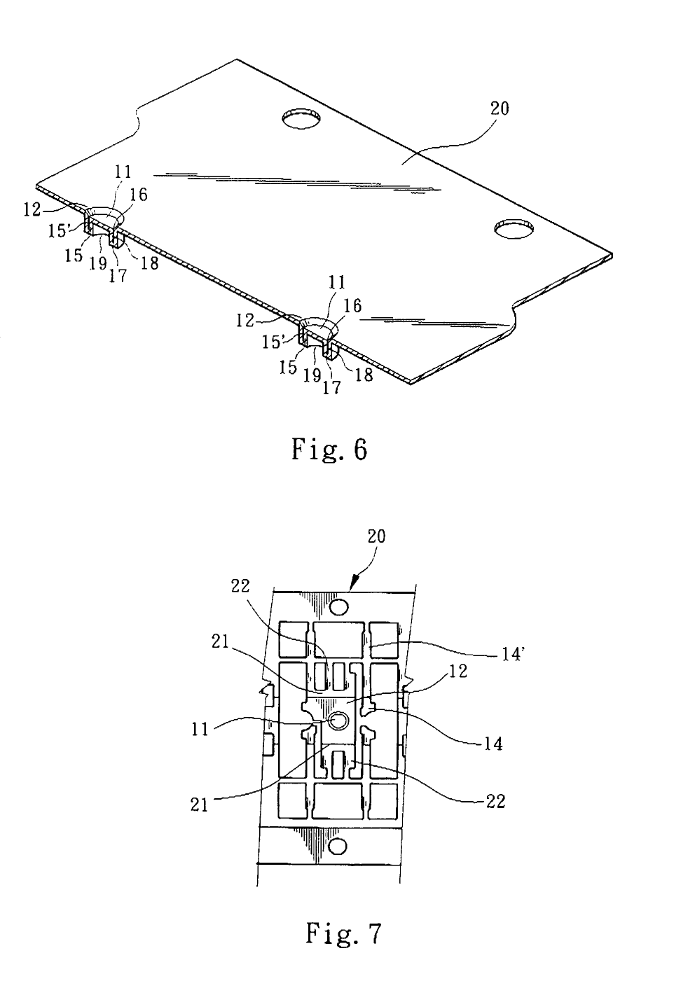

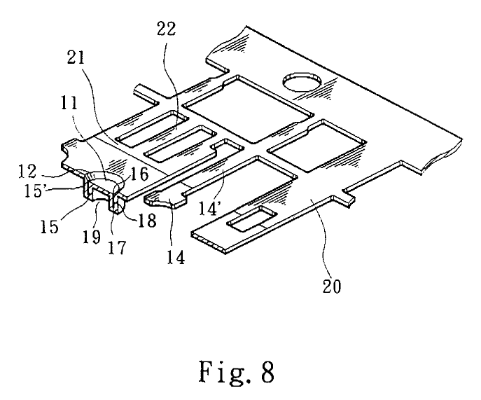

FIG. 3 is a flow chart of the method of the present invention, including steps of:
a. selecting a metal plane blank 20 with better extensibility and conductivity, the blank 20 being downward punched with an upper mold section P1 to form a hollow semispherical central section 12 downward protruding from the blank 20 as shown in FIG. 4;
b. punching the concave central section 12 with a lower mold section P2 in a direction reverse to the moving direction of the upper mold section P1, whereby the bottom of the central section 12 is formed with continuous arranged rigid walls 15, 15′ which define an open cavity 19 as shown in FIG. 5;
c. pressing a predetermined position of the central section 12 with another upper mold section P3 in a direction the same as the moving direction of the upper mold section P1 to form a bowl seat 11, whereby a model body 10 with rigid walls 15, 15′ having ridge section 16 and hollow section 17 is formed on the blank 20 as shown in FIG. 6; and
d. forming grid structure 22 on two sides or the periphery 21 of the central section 12 of the blank 20 as shown in FIGS. 7 and 8, the grid structure 22 shortening the conducting distance between the model body 10 and outer side, whereby the dissipation of the heat generated by the chip x can be speeded.

Referring to FIG. 8, the model body 10 is structurally characterized in that:
1. The rigid walls 15, 15′ are continuously arranged and adjacent to each other to define a gap 18;
2. Each rigid wall 15, 15′ has a ridge section 16 and a hollow section 17 adjoining two adjacent rigid walls 15, 15′.
3. At least one end of the ridge section 16 or hollow section 17 of the rigid wall 15, 15′ communicates with outer side;
4. The lower section of the bowl seat 11 of the central section 12 is formed with a cavity 19 which is defined by the rigid wall 15 and communicates with outer side;
5. The ridge section 16 or hollow section 17 of the rigid wall 15, 15′ and the cavity 19 communicate with outer side and the model body 10 is formed with the grid structure 22 so as to enhance the convection and heat-dissipating effect.
6. The steps a and b can be repeated in a modified embodiment.

According to the above arrangement, in addition to the contact pins 14′, the total area of the inner face and outer face of the rigid walls 15, 15′ and the open cavity 19 of the central section 12 of the model body 10 also serve to dissipate the heat. Therefore, better heat-radiating efficiency can be achieved.

The above embodiments are only used to illustrate the present invention, not intended to limit the scope thereof. Many modifications of the above embodiments can be made without departing from the spirit of the present invention.

1. A light-emitting diode structure comprising a model body having a central section and a connecting section connected with the central section, the central section having a bowl seat for fixing therein a chip, the central section being defined as a cathode end, the connecting section having at least two contact pins as anode ends, a lead being connected between the chip and the connecting section, said light-emitting diode structure being characterized in that at least one layer of rigid wall is arranged from the central section of the model body to outer side, the rigid wall defining a cavity, each rigid wall having a continuously arranged structure defining a gap.

2. The light-emitting diode structure as claimed in claim 1, wherein each rigid wall has a ridge section and a hollow section.

3. The light-emitting diode structure as claimed in claim 2, wherein the hollow sections of each two adjacent rigid walls are adjoined with each other.

4. The light-emitting diode structure as claimed in claim 1, wherein the cavity is formed under the bowl seat of the central section to communicate with outer side.

5. The light-emitting diode structure as claimed in claim 4, wherein the cavity is defined by the rigid wall.

6. The light-emitting diode structure as claimed in claim 2, wherein at least one end of the ridge section or hollow section of each rigid wall communicates with outer side.

7. The light-emitting diode structure as claimed in claim 1, wherein a grid structure is formed on two sides or a periphery of the central section of the model body.

8. A method for manufacturing a light-emitting diode structure, comprising steps of:
a. distributing a conductive metal plane blank in a production line and punching the blank with an upper mold section to form a concave central section protruding from the blank;
b. punching the concave central section with a lower mold section in a direction reverse to the moving direction of the upper mold section, whereby a bottom of the central section is formed with at least one rigid wall defining a cavity; and
c. pressing a predetermined position of the central section with another upper mold section in a direction the same as the moving direction of the upper mold section to form a bowl seat on the central section for fixing a chip in the bowl seat.

9. The method for manufacturing the light-emitting diode structure as claimed in claim 8, further comprising a step of:
e. forming a grid structure on two sides or a periphery of the central section.

10. The method for manufacturing the light-emitting diode structure as claimed in claim 8, wherein each rigid wall has a ridge section and a hollow section.

11. The method for manufacturing the light-emitting diode structure as claimed in claim 10, wherein the hollow sections of each two adjacent rigid walls are adjoined with each other.

12. The method for manufacturing the light-emitting diode structure as claimed in claim 8, wherein the cavity is formed under the bowl seat of the central section to communicate with outer side.

13. The method for manufacturing the light-emitting diode structure as claimed in claim 12, wherein the cavity is defined by the rigid wall.

14. The method for manufacturing the light-emitting diode structure as claimed in claim 2, wherein at least one end of the ridge section or hollow section of each rigid wall communicates with outer side.
